(19) United States
(12) Patent Application Publication
(10) Pub. No.: US 2010/0084679 A1
(43) Pub. Date: Apr. 8, 2010

(54) LIGHT-EMITTING DEVICE

(75) Inventors: Min-Hsun Hsieh, Hsinchu (TW); Tzu-Chieh Hsu, Hsinchu (TW); Ta-Cheng Hsu, Hsinchu (TW); Wei-Chih Peng, Hsinchu (TW); Ya-Ju Lee, Hsinchu (TW)

Correspondence Address: BACON & THOMAS, PLLC, 625 SLATERS LANE, FOURTH FLOOR, ALEXANDRIA, VA, 22314-1176, US

(73) Assignee: EPISTAR CORPORATION, Hsinchu (TW)

(21) Appl. No.: 12/613,749

(22) Filed: Nov. 6, 2009

Related U.S. Application Data
(63) Continuation-in-part of application No. 11/984,248, filed on Nov. 15, 2007.
Application No. 11/984,248 is a continuation-in-part of application No. 11/326,750, filed on Jan. 6, 2006, now Pat. No. 7,489,068.

(30) Foreign Application Priority Data
Nov. 11, 2008 (TW) 097143652

(51) Int. Cl. H01L 33/00; H01L 21/30

(52) U.S. Cl. 257/98; 438/29; 257/E33.064; 257/E21.211

(57) ABSTRACT

A light-emitting device having a substrate, a light-emitting stack, and a transparent connective layer is provided. The light-emitting stack is disposed above the substrate and comprises a first diffusing surface. The transparent connective layer is disposed between the substrate and the first diffusing surface of the light-emitting stack; an index of refraction of the light-emitting stack is different from that of the transparent connective layer.

### RELATED APPLICATION

This application is a continuation-in-part of U.S. patent application, Ser. No. 11/984248, entitled “LIGHT-EMITTING DEVICE”, filed on Nov. 15, 2007; and claims the right of priority based on TW application Ser. No. 097143652, filed “Nov. 11, 2008”, entitled “LIGHT-EMITTING DEVICE”; the contents of which are incorporated herein by reference.

### BACKGROUND

1. Technical Field

The present invention relates to a light-emitting device and in particular to a light-emitting device having a diffusing surface.

2. Description of the Related Art

Light-emitting devices have been employed in a wide variety of applications, including optical displays, traffic lights, data storage apparatus, communication devices, illumination apparatus, and medical treatment equipment. How to improve the light-emitting efficiency of light-emitting devices is an important issue in this art.

Referring to FIG. 1, according to Snell's law, when a light is directed from one material with a refractive index n1 towards another material with a refractive index n2, the light will be refracted if its incident angle is smaller than a critical angle θ_{C}. Otherwise, the light will be totally reflected from the interface between the two materials. In other words, when a light beam generated from a light-emitting diode (LED) travels across an interface from a material of a higher refractive index to a material of a lower refractive index, the angle between the incident light beam and the reflected light beam must be equal or less than 2θ_{C} for the light to be emitted out. It means that when the light generated from the LED travels from an epitaxial layer having a higher refractive index to a medium having a lower refractive index, such as a substrate, air and so on, a portion of the light will be refracted into the medium, and another portion of the light with an incident angle larger than the critical angle will be reflected back to the epitaxial layer of the LED. Owing to the environment surrounding the epitaxial layer of the LED having a lower refractive index, the reflected light is reflected back and forth for several times inside the LED and finally a certain portion of said reflected light is absorbed.

In U.S. Patent Publication No. 2002/0017652 entitled “Semiconductor Chip for Optoelectronics”, an epitaxial layer of a light-emitting device forming on a non-transparent substrate is etched to form a micro-reflective structure having a multiplicity of semi-spheres, pyramids, or cones, and then a metal reflective layer is deposited on the epitaxial layer. The top of the micro-reflective structure is bonded to a conductive carrier (silicon wafer), and then the non-transparent substrate of the epitaxial layer is removed. All the light generated from the light-emitting layer and incident to the micro-reflective structure will be reflected back to the epitaxial layer and emitted out of the LED with a direction perpendicular to a light-emitting surface. Therefore, the light will not be restricted by the critical angle any more.

### SUMMARY

The present invention is to provide a light-emitting device comprising a substrate, a light-emitting stack, and a transparent connective layer. As embodied and broadly described herein, the light-emitting stack comprising a first diffusing surface adjacent to the transparent connective layer. The transparent connective layer is disposed between the substrate and the first diffusing surface of the light-emitting stack.

According to one embodiment of the present invention, the first diffusing surface is a rough surface.

According to one embodiment of the present invention, the rough surface is a convex-concave surface.

According to one embodiment of the present invention, the light-emitting stack includes a first semiconductor layer, a light-emitting layer and a second semiconductor layer. The first semiconductor layer is disposed above the substrate and has the diffusing surface. The light-emitting layer is disposed on a portion of the first semiconductor layer. The second semiconductor layer is disposed on the light-emitting layer.

According to one embodiment of the present invention, the second semiconductor layer has a second diffusing surface.

According to one embodiment of the present invention, the light-emitting device further includes a first electrode and a second electrode. The first electrode is disposed on the first semiconductor layer where the light-emitting layer is not disposed thereon, and the second electrode is disposed on the second semiconductor layer.

According to one embodiment of the present invention, the light-emitting device further includes a first transparent conductive layer disposed between the first electrode and the first semiconductor layer.

According to one embodiment of the present invention, the light-emitting device further includes a first reaction layer and a second reaction layer. The first reaction layer is disposed between the substrate and the transparent connective layer, and the second reaction layer is disposed between the transparent connective layer and the light-emitting stack.

According to one embodiment of the present invention, the light-emitting device further includes a transparent conductive layer disposed between the second semiconductor layer and the second electrode.

According to one embodiment of the present invention, the light-emitting stack and the transparent connective layer have different refractive indices, such that the possibility of light extraction of the light-emitting device is raised, and the light-emitting efficiency is improved, too.

According to one embodiment of the present invention, the light-emitting device further includes a reflective layer disposed between the transparent connective layer and the substrate. The transparent connective layer includes a surface that is flat.

According to one embodiment of the present invention, the light-emitting device further includes a transparent conductive layer between the transparent connective layer and the first diffusing surface, and the transparent connective layer includes a plurality of sub-layers.

The present invention is also to provide a method for manufacturing a light-emitting device, comprising providing a light-emitting stack having a first surface; roughening the first surface into a first diffusing surface; forming a transparent connective layer on the first diffusing surface; smoothing a surface of the transparent connective layer opposite to the first diffusing surface; and attaching or forming a substrate on the transparent connective layer.

### BRIEF DESCRIPTION OF THE DRAWINGS

The accompanying drawings incorporated herein provide a further understanding of the invention therefore constitute a part of this specification. The drawings illustrating embodiments of the invention, together with the description, serve to explain the principles of the invention.

FIG. 1 is a schematic diagram illustrating the Snell's law.

FIG. 2 is a schematic diagram showing a light field of the present invention.

FIG. 3 is a schematic, cross-sectional view showing a light-emitting device according to a preferred embodiment of the present invention.

FIG. 4 is a schematic, cross-sectional view showing a light-emitting device having two diffusing surfaces according to a preferred embodiment of the present invention.

FIG. 5 is a schematic, cross-sectional view showing a light-emitting device having transparent conductive layers according to a preferred embodiment of the present invention.

FIG. 6 is a schematic, cross-sectional view showing a light-emitting device having reaction layers according to a preferred embodiment of the present invention.

FIG. 7 is a schematic, cross-sectional view showing a light-emitting device according to another preferred embodiment of the present invention.

FIG. 8 is a schematic, cross-sectional view showing a light-emitting device according to another preferred embodiment of the present invention.

FIG. 9 is a schematic, cross-sectional view showing a light-emitting device according to another preferred embodiment of the present invention.

FIG. 10 is a flow chart showing a method for manufacturing a light-emitting device according to a preferred embodiment of the present invention.

FIG. 11 is a schematic, cross-sectional view showing a light-emitting device according to another preferred embodiment of the present invention.

FIG. 12 is a schematic, cross-sectional view showing a light-emitting device according to another preferred embodiment of the present invention.

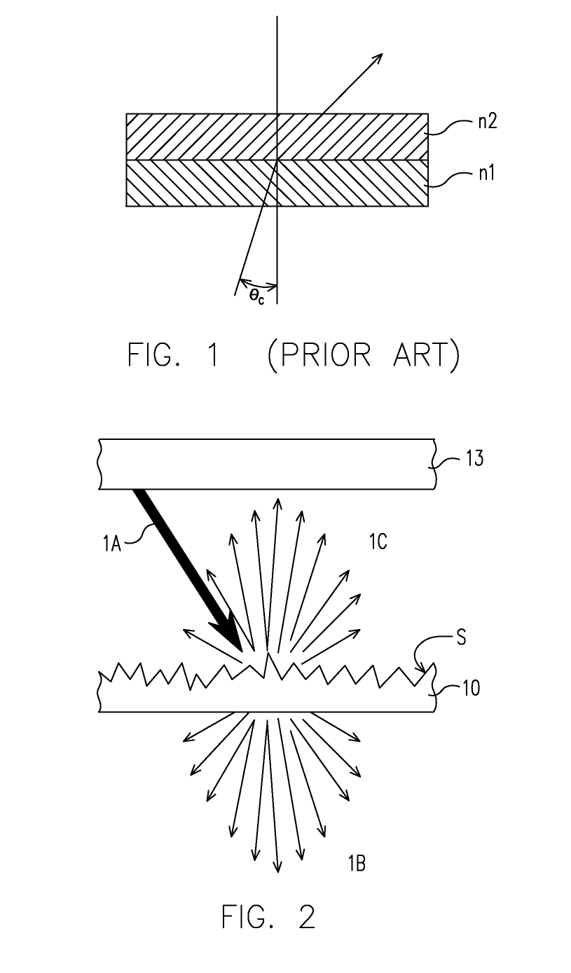

### DETAILED DESCRIPTION OF THE EMBODIMENTS

Reference will now be made in detail to the present preferred embodiments of the invention, examples of which are illustrated in the accompanying drawings. Wherever possible, the same reference numbers are used in the drawings and the descriptions hereof refer to the same or like parts.

FIG. 2 is a schematic diagram showing a light field of the present invention. Referring to FIG. 2, when a light 1A generated from a light-emitting layer 13 is directed towards a diffusing surface S, a portion of the light 1A is refracted to a substrate 10 to form a light field 1B, and another portion of the light 1A is diffused by the diffusing surface S to form a light field 1C. The light, which is restricted to the critical angle, is diffused and redirected by the diffusing surface S to the light-emitting layer 13, and then is extracted from the front of the light-emitting layer 13, therefore the light extraction efficiency is enhanced. If a portion of the diffused light is totally reflected to the diffusing surface S owing to its incident angle greater than the critical angle, it will be diffused again to change its incident angle, thus improving the light extraction efficiency. Therefore, no matter how many times the light experiences the total internal reflection, the light will be diffused by the diffusing surface S to increase the probability of light extraction and enhance the light-emitting efficiency.

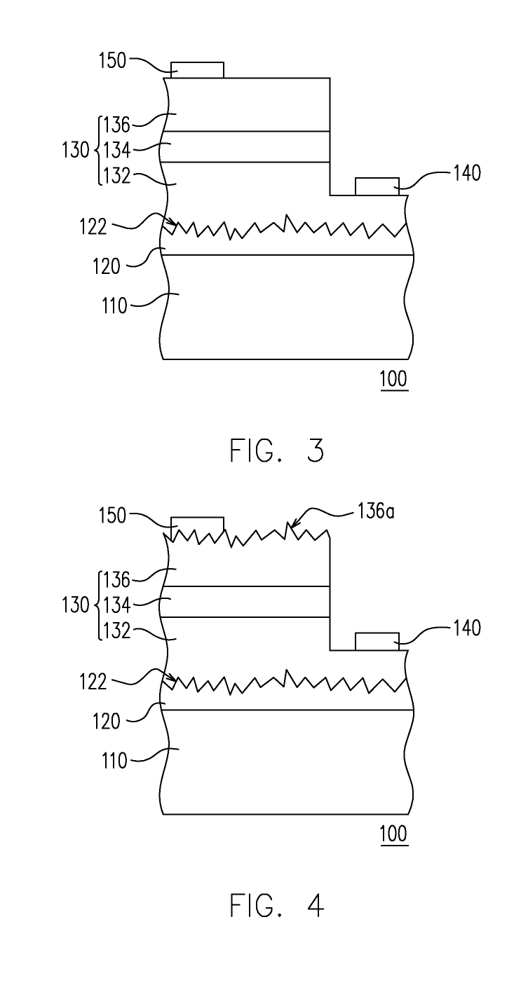

FIG. 3 is a schematic cross-sectional view showing a light-emitting device according to a preferred embodiment of the present invention. The light-emitting device 100 includes a substrate 110, a transparent connective layer 120, a light-emitting stack 130, a first electrode 140, and a second electrode 150. In one embodiment of the present invention, the substrate is a transparent substrate and the material of the substrate 110 is selected from one of the group consisting of GaP, SiC, Al₂O₃, ZnO, Si, Cu, and glass. The transparent connective layer 120 is formed on the substrate 110, and can be a bonding layer. The material of the transparent connective layer 120 can be polyimide, benzocyclobutene (BCB), perfluorocyclobutane (PFCB), epoxy, Su8, indium tin oxide, SiNₓ, SiO₂, TiO₂, MgO, spin-on glass (SOG), or the combination thereof. The light-emitting stack 130 includes a first semiconductor layer 132 having a first conductivity-type, a light-emitting layer 134, and a second semiconductor layer 136 having a second conductivity-type opposite to the first conductivity-type. The refractive index of the light-emitting stack 130 is different from that of the transparent connective layer 120. For exhibiting Lambertian Reflectance, the difference of the refractive indices of the transparent connective layer 120 and the light-emitting stack 130 is at least 0.1. The first semiconductor layer 132 attaches to the substrate 110 through the transparent connective layer 120, and has a first diffusing surface 122 next to the transparent connective layer 120. The material of the first semiconductor layer 132, the light-emitting layer 134 and the second semiconductor layer 136 can be AlGaInP, MN, GaN, AlGaN, InGaN or AlInGaN. An upper surface of the first semiconductor layer 132 has an epitaxy region and an electrode region. The light-emitting layer 134 is formed on the epitaxy region of the first semiconductor layer 132. The second semiconductor layer 136 is formed on the light-emitting layer 134. The first electrode 140 is formed on the electrode region of the first semiconductor layer 132. The second electrode 150 is formed on the second semiconductor layer 136. Referring to FIG. 4, an upper surface of the second semiconductor layer 136 may further include a second diffusing surface 136a to increase the light extracted from the diffusing surface 136a. For further increasing the light extracted from the substrate, it is also preferred to form diffusing surfaces on either or both sides of the substrate.

The way to form the first semiconductor layer 132, the light-emitting layer 134 and the second semiconductor layer 136 on the substrate 110 as shown in FIGS. 3 and 4 is to use an epitaxy method, such as MOVPE method (Metallic Organic Vapor Phase Epitaxy). The diffusing surfaces 122 or 136a, can be rough surfaces formed during the epitaxy process by carefully tuning and controlling the process parameters, such as gas flow rate, chamber pressure, chamber temperature etc. The diffusing surfaces can also be formed in a periodic, quasi-periodic, or random pattern by removing a part of the first semiconductor layer 132 or the second semiconductor layer 136 by wet etching or dry etching.

In another embodiment of the present invention, the diffusing surface 122 of the first semiconductor layer 132 or the diffusing surfaces 136a of the second semiconductor layer 136 includes a plurality of micro-protrusions. The shape of the micro-protrusions can be a semi-sphere, a pyramid, or a pyramid polygon. The light extraction efficiency is therefore enhanced by the surface roughened in a manner of micro-protrusions.

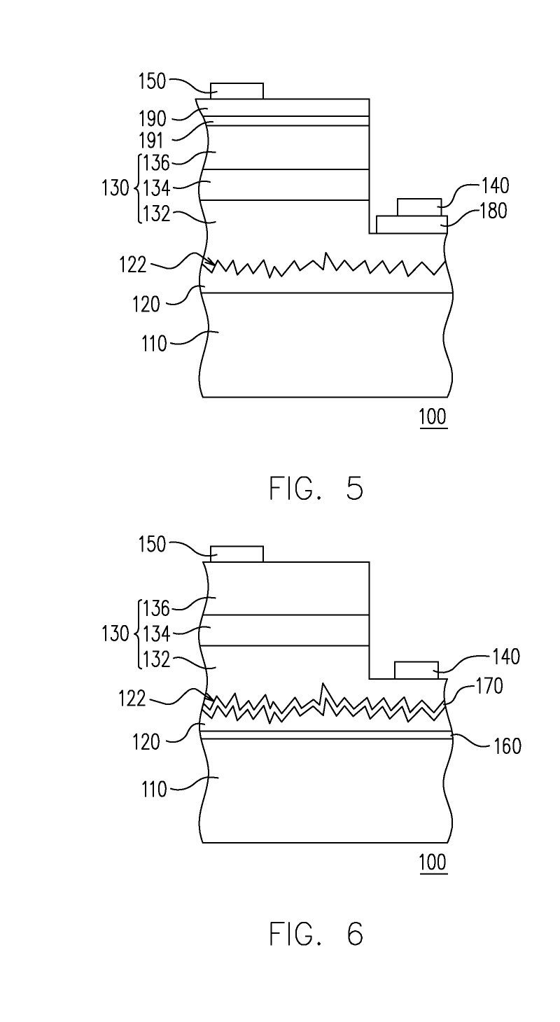

In one embodiment of the present invention, referring to FIG. 5, a first transparent conductive layer 180 is selectively disposed between the first electrode 140 and the first semiconductor layer 132. The material of the first transparent conductive layer 180 includes indium tin oxide, cadmium tin oxide, antimony tin oxide, zinc aluminum oxide, or zinc tin oxide. Similarly, a second transparent conductive layer 190 is selectively disposed between the second semiconductor layer 136 and the second electrode 150. The second transparent conductive layer 190 is mainly served to spread current in at least lateral direction. In one embodiment, the thickness of the second transparent conductive layer 190 is thick enough such that current is swiftly laterally spread throughout the second transparent conductive layer 190. The thickness (t) of the transparent conductive layer 190 is not less than 400 nm. In another embodiment, the second transparent conductive layer 190 is in a shape of rectangle complying with the shape of the light-emitting device, for example, the length (L) of the transparent conductive layer 190 is at least twice of the width (W) of the transparent conductive layer 190, preferably L/W is around 2˜5. The thickness of the second transparent conductive layer 190 is preferably around 400 nm to 1000 nm. The sheet resistance is preferably less than 9 ohm/square. The material of the second transparent conductive layer 190 includes transparent conductive oxide, such as indium tin oxide, cadmium tin oxide, antimony tin oxide, zinc aluminum oxide, or zinc tin oxide.

In another embodiment, the light-emitting device 100 further includes a conductive inter-layer (CIL) 191 interposing between the transparent conductive layer 190 and the second semiconductor layer 136 for improving the in-between contact resistance. The conductive inter-layer 191 includes a semiconductor material having a conductivity-type opposite to that of the second semiconductor layer 136. For example, in a GaN-based light-emitting device, the conductive inter-layer 191 includes heavily Si-doped InGaN, and the Si dopant concentration is around the level of 10¹⁸ to 10²⁰ cm⁻³. A tunneling junction is formed between the conductive inter-layer 191 and the second semiconductor layer 136, and an ohmic contact is also formed between the conductive inter-layer 191 and the transparent conductive layer 190 such that the series resistance of the device is reduced.

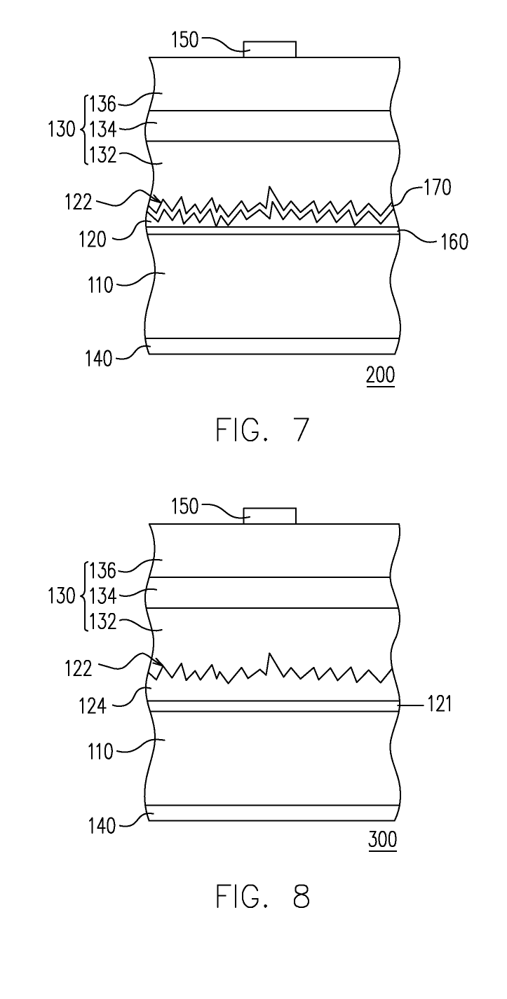

Further referring to FIG. 6, a first reaction layer 160 can be selectively disposed between the substrate 110 and the transparent connective layer 120, and a second reaction layer 170 can be selectively disposed between the transparent connective layer 120 and the first semiconductor layer 132, thereby increasing the adhesion of the transparent connective layer 120. The material of the first reaction layer 160 and the second reaction layer 170 can be SiNx, Ti or Cr.

FIG. 7 is a schematic cross-sectional view showing a vertical-type light-emitting device 200 according to another preferred embodiment of the present invention. The substrate 110 is a transparent conductive substrate, for example, ZnO. The first semiconductor layer 132 with the second reaction layer 170 underneath is coupled to a gel-state transparent connective layer 120, and the protrusion part of the second reaction layer 170 penetrates through the transparent connective layer 120 and ohmically contacts with the first reaction layer 160 in the case of the first reaction layer 160 and the second reaction layer 170 both being conductive. A first electrode 140 is formed on the lower surface of the substrate 110, and a second electrode 150 is formed on the upper surface of the second semiconductor layer 136. Similarly, a transparent conductive layer (not shown) can be selectively disposed between the second electrode 150 and the second semiconductor layer 136. The material of the transparent conductive layer includes indium tin oxide, cadmium tin oxide, antimony tin oxide, zinc aluminum oxide or zinc tin oxide.

FIG. 8 is a schematic cross-sectional view showing a light-emitting device according to another preferred embodiment of the present invention. Referring to FIG. 8, the structure of the light-emitting device 300 is similar to that of the light-emitting device 100 shown in FIG. 3. The difference between them is that a transparent conductive connective layer 124 replaces the transparent connective layer 120 such that the light-emitting device 300 is electrically conductive vertically. The transparent conductive connective layer 124 is composed of intrinsically conductive polymer or polymer having conductive material distributed therein. The conductive material includes indium tin oxide, cadmium tin oxide, antimony tin oxide, zinc oxide, zinc tin oxide, Au or Ni/Au. The first electrode 140 is formed under a transparent conductive substrate 112, and the second electrode 150 is formed on the second semiconductor layer 136. In addition, a reflective layer 121 can be formed in-between the transparent conductive connective layer 124 and the substrate 110 for reflection. The transparent conductive connective layer 124 includes a surface that can be smoothed to contact with the reflective layer 121. The substrate 110 can be a plating substrate, such as Cu or Si.

In one embodiment of the present invention, the light-emitting device 300 further includes a transparent conductive layer (not shown) disposed between the second electrode 150 and the second semiconductor layer 136. The material of the transparent conductive layer includes indium tin oxide, cadmium tin oxide, antimony tin oxide, zinc aluminum oxide, zinc tin oxide, AlGaAs, GaN, GaP, InO, SnO, antimony tin oxide, ZnO, GaAs, GaAsP, or the combination thereof.

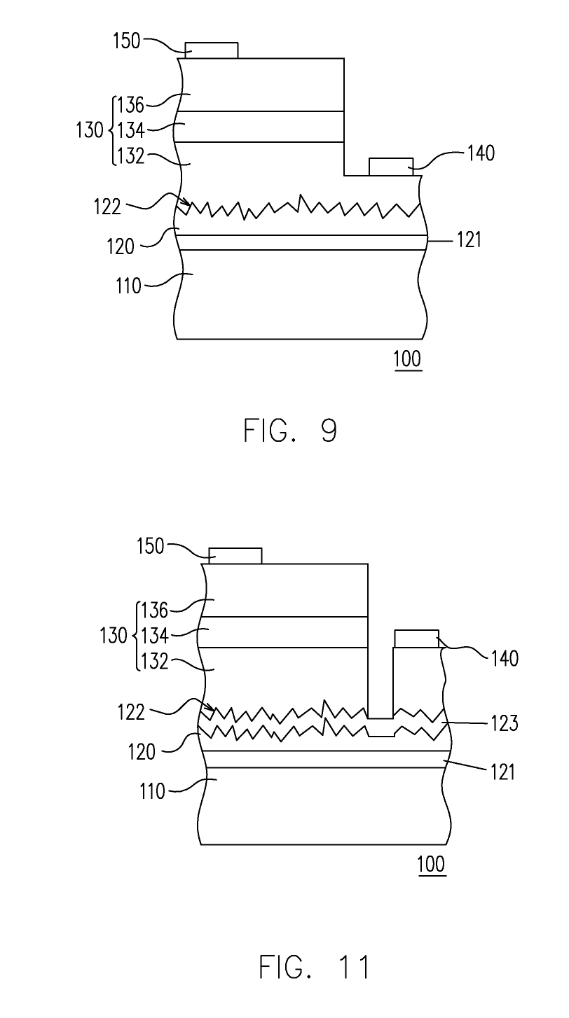

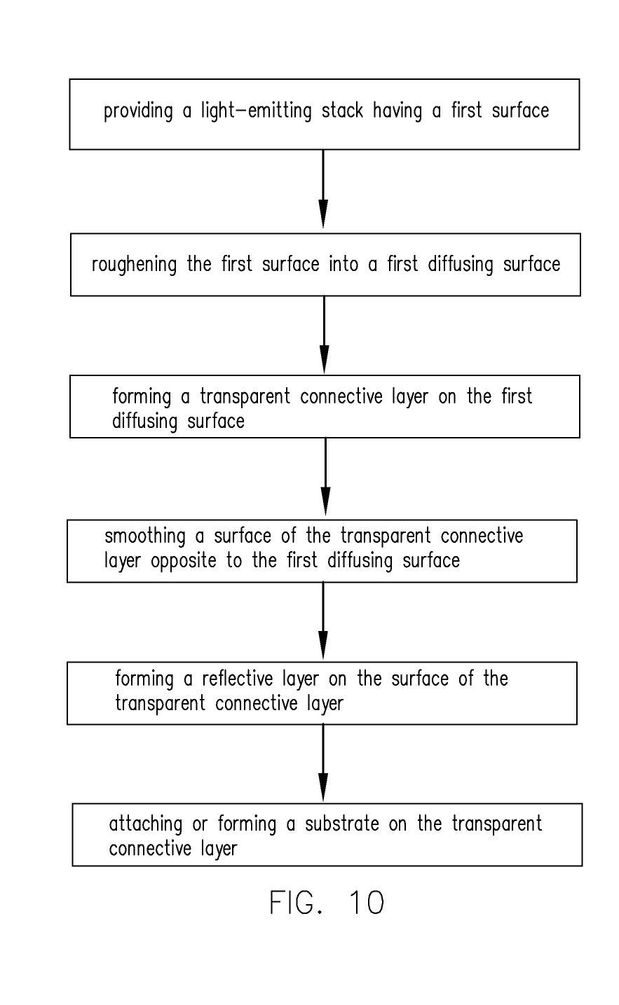

In one embodiment of the present invention, referring to FIG. 9, the reflective layer 121 is formed in-between the transparent connective layer 120 and the substrate 110 for reflecting the light refracted by the first diffusing surface 122. The transparent connective layer 120 includes a surface that is flat for contacting with the reflective layer 121. Moreover, the difference of the refractive indices between the transparent connective layer 120 and the first semiconductor layer 132 is at least 0.1. Because the light was refracted by the first diffusing surface 122, its incident angle has been changed. When the light is reflected to the first diffusing surface 122, it will be diffused to change its incident angle again, thus improving the light extraction efficiency. Accordingly, the reflective layer 121 associating with the transparent connective layer 120 and the first diffusing surface 122 can exhibit Lambertian Reflectance. Therefore, no matter how many times the light experiences the total internal reflection, the light will be diffused by the first diffusing surface 122 to increase the probability of light extraction and enhance the light-emitting efficiency. In addition, the reflective layer 121 also can be a bonding layer. The material of the reflective layer 121 can be In, Sn, Al, Au, Pt, Zn, Ag, Ti, Pb, Ge, Cu, Ni, AuBe, AuGe, AuZn, PbSn, or the combination thereof. The substrate 110 is not restricted to be transparent and can be a plating substrate.

Referring to FIG. 10, a method for manufacturing a semiconductor device includes providing the semiconductor stack 130 having the first surface; roughening the first surface into the first diffusion surface 122; forming the transparent connective layer 120 on the first diffusing surface 122; smoothing a surface of the transparent connective layer 120 opposite to the first diffusing surface 122; and attaching or forming the substrate 110 on the transparent connective layer 120. In addition, before attaching or forming the substrate 110 on the transparent connective layer 120, the method further includes forming the reflective layer 121 on the surface of the transparent connective layer 120. The surface of the transparent connective layer 120 contacting with the reflective layer 121 and opposite to the first diffusing surface 122 is polished to become a flat surface by a polishing method, such as CMP (Chemical Mechanical Polishing). Then, the reflective layer 121 is formed on the flat surface, and the interface between the reflective layer 121 and the transparent connective layer 120 is flat, thus improving the reflectance. However, if the transparent connective layer 120 is glue, the surface of the transparent connective layer 120 does not have to be polished.

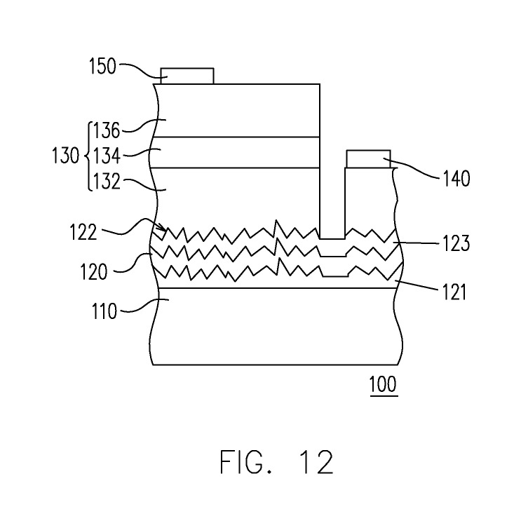

In one embodiment of the present invention, referring to FIG. 11, the reflective layer 121 is between the transparent connective layer 120 and the substrate 110 for reflecting the light refracted by the first diffusing surface 122 and bonding the transparent connective layer 120 to the substrate 110. Optionally, the reflective layer 121 can also include a bonding layer (not shown) for bonding the substrate 110. The transparent connective layer 120 includes a plurality of sub-layers (not shown) comprising different thicknesses and materials, and therefore the plurality of sub-layers includes different refractive indices. Because of the different refractive indices among the plurality of sub-layers, the transparent connective layer can perform as a Distributed Bragg Reflector (DBR). A surface of the transparent connective layer 120 can be smoothed. Otherwise, it can be rough when the transparent connective layer 120 deposits on the semiconductor stack 130 as shown in FIG. 12. The DBR having at least two different materials can be polyimide, benzocyclobutene (BCB), perfluorocyclobutane (PFCB), epoxy, Sub, indium tin oxide, SiNₓ, spin-on glass (SOG), SiO₂, TiO₂, or MgO. In addition, there is a transparent conductive layer 123 between the transparent connective layer 120 and the first diffusing surface 122 for spreading current. A bottom surface of the transparent conductive layer 123 can be rough. The material of the transparent conductive layer 123 can be indium tin oxide, cadmium tin oxide, AlGaAs, GaN, GaP, InO, SnO, antimony tin oxide, ZnO, GaAs, GaAsP, zinc aluminum oxide, zinc tin oxide, or the combination thereof.

It will be apparent to those skilled in the art that various modifications and variations can be made to the structures in accordance with the present invention without departing from the scope or spirit of the invention. In view of the foregoing, it is intended that the present invention cover modifications and variations of this invention provided they fall within the scope of the following claims and their equivalents.

What is claimed is:

1. A light-emitting device, comprising:
a substrate;
a light-emitting stack above the substrate and having a first diffusing surface; and
a transparent connective layer between the substrate and the first diffusing surface;
wherein a surface of the transparent connective layer adjacent to the substrate is a flat surface.

2. The light-emitting device according to claim 1, further comprising a first transparent conductive layer above the light-emitting stack.

3. The light-emitting device according to claim 2, wherein the thickness of the first transparent conductive layer is not less than 400 nm.

4. The light-emitting device according to claim 2, wherein the sheet resistance of the first transparent conductive layer is less than 9 ohms/square.

5. The light-emitting device according to claim 2, wherein the length of the first transparent conductive layer is 2 to 5 times of the width of the first transparent conductive layer.

6. The light-emitting device according to claim 2, wherein the first transparent conductive layer comprises a material selected from the group consisting of indium tin oxide, cadmium tin oxide, antimony tin oxide, zinc aluminum oxide, zinc tin oxide, AlGaAs, GaN, GaP, InO, SnO, antimony tin oxide, ZnO, GaAs, GaAsP, and the combination thereof.

7. The light-emitting device according to claim 1, wherein the substrate is transparent and comprises a material selected from the group consisting of GaP, SiC, Al₂O₃, ZnO, Cu, Si, and glass.

8. The light-emitting device according to claim 1, wherein the transparent connective layer is a bonding layer.

9. The light-emitting device according to claim 8, wherein the bonding layer comprises a material selected from the group consisting of polyimide, benzocyclobutene (BCB), perfluorocyclobutane (PFCB), epoxy, Su8, indium tin oxide, SiNₓ, spin-on glass, SiO₂, TiO₂, MgO, and the combination thereof.

10. The light-emitting device according to claim 1, wherein the first diffusing surface comprises a rough surface.

11. The light-emitting device according to claim 10, wherein the rough surface comprises a convex-concave surface.

12. The light-emitting device according to claim 10, further comprising a reflective layer between the transparent connective layer and the substrate.

13. The light-emitting device according to claim 1, wherein the light-emitting stack has a second diffusing surface opposite to the first diffusing surface.

14. The light-emitting device according to claim 1, wherein the transparent connective layer comprises a plurality of sub-layers.

15. The light-emitting device according to claim 14, wherein the plurality of sub-layers is a DBR.

16. The light-emitting device according to claim 14, wherein the plurality of sub-layers comprises at least two different materials selected from the group consisting of polyimide, benzocyclobutene (BCB), perfluorocyclobutane (PFCB), epoxy, Su8, indium tin oxide, SiNₓ, spin-on glass, SiO₂, TiO₂, and MgO.

17. The light-emitting device according to claim 1, further comprising a transparent conductive layer between the first diffusing surface and the transparent connective layer.

18. The light-emitting device according to claim 17, wherein the transparent conductive layer comprises a material selected from the group consisting of indium tin oxide, cadmium tin oxide, AlGaAs, GaN, GaP, InO, SnO, antimony tin oxide, ZnO, GaAs, GaAsP, zinc aluminum oxide, zinc tin oxide, and the combination thereof.

19. The light-emitting device according to claim 17, wherein the transparent conductive layer comprises a rough bottom surface.

20. A method for manufacturing a light-emitting device, comprising:
providing a light-emitting stack having a first surface;
roughening the first surface into a first diffusing surface;
forming a transparent connective layer on the first diffusing surface;
smoothing a surface of the transparent connective layer opposite to the first diffusing surface; and
attaching or forming a substrate on the transparent connective layer.

21. The method for manufacturing the light-emitting device according to claim 20, wherein the transparent connective layer comprises a material selected from the group consisting of polyimide, benzocyclobutene (BCB), perfluorocyclobutane (PFCB), epoxy, Sub, indium tin oxide, SiNₓ, spin-on glass, SiO₂, TiO₂, MgO, and the combination thereof.

22. The method for manufacturing the light-emitting device according to claim 20, wherein the transparent connective layer comprises a plurality of sub-layers.

23. The method for manufacturing the light-emitting device according to claim 22, wherein the plurality of sub-layers is a DBR.

24. The method for manufacturing the light-emitting device according to claim 23, wherein the DBR comprises at least two different materials selected from the group consisting of polyimide, benzocyclobutene (BCB), perfluorocyclobutane (PFCB), epoxy, Sub, indium tin oxide, SiNₓ, spin-on glass, SiO₂, TiO₂, and MgO.

25. The method for manufacturing the light-emitting device according to claim 20, before attaching or forming a substrate on the transparent connective layer, further comprising forming a reflective layer on the surface of the transparent connective layer.

26. The method for manufacturing the light-emitting device according to claim 20, wherein the first diffusing surface comprises a rough surface.

27. The method for manufacturing the light-emitting device according to claim 26, wherein the rough surface comprises a convex-concave surface.

28. The method for manufacturing the light-emitting device according to claim 20, before forming a transparent connective layer on the first diffusing surface, further comprising forming a transparent conductive layer between the first diffusing surface and the transparent connective layer.

29. The method for manufacturing the light-emitting device according to claim 28, wherein the transparent conductive layer comprises a material selected from the group consisting of indium tin oxide, cadmium tin oxide, AlGaAs, GaN, GaP, InO, SnO, antimony tin oxide, ZnO, GaAs, GaAsP, zinc aluminum oxide, zinc tin oxide, and the combination thereof.

30. The method for manufacturing the light-emitting device according to claim 28, wherein the transparent conductive layer comprises a rough bottom surface.

31. A light-emitting device, comprising:
a substrate;
a light-emitting stack above the substrate and having a first diffusing surface;
a transparent connective layer between the substrate and the first diffusing surface; and
a reflective layer between the transparent connective layer and the substrate; wherein a surface of the transparent connective layer adjacent to the substrate is a rough surface.

32. The light-emitting device according to claim 31, wherein the transparent connective layer comprises a DBR.

33. The light-emitting device according to claim 32, wherein the DBR comprises at least two different materials selected from the group consisting of polyimide, benzocyclobutene (BCB), perfluorocyclobutane (PFCB), epoxy, Su8, indium tin oxide, SiNₓ, spin-on glass, SiO₂, TiO₂, and MgO.

34. The light-emitting device according to claim 31, wherein the reflective layer comprises a bonding layer.

35. The light-emitting device according to claim 31, wherein the first diffusing surface comprises a rough surface.

36. The light-emitting device according to claim 35, wherein the rough surface comprises a convex-concave surface.

37. The light-emitting device according to claim 31, further comprising a transparent conductive layer between the first diffusing surface and the transparent connective layer.

38. The light-emitting device according to claim 37, wherein the transparent conductive layer comprises a material selected from the group consisting of indium tin oxide, cadmium tin oxide, AlGaAs, GaN, GaP, InO, SnO, antimony tin oxide, ZnO, GaAs, GaAsP, zinc aluminum oxide, zinc tin oxide, and the combination thereof.

39. The light-emitting device according to claim 37, wherein the transparent conductive layer comprises a rough bottom surface.
